(19) United States
(12) Patent Application Publication
(10) Pub. No.: US 2011/0104893 A1
(43) Pub. Date: May 5, 2011

(54) METHOD FOR FABRICATING MOS TRANSISTOR

(76) Inventors: Jubao Zhang, Singapore (SG); Hang Hu, Singapore (SG); Hong Liao, Singapore (SG)

(21) Appl. No.: 12/611,932

(22) Filed: Nov. 4, 2009

(51) Int. Cl. H01L 21/768

(52) U.S. Cl. 438/653; 438/655; 257/E21.584

(57) ABSTRACT

A method for fabricating metal-oxide semiconductor (MOS) transistor is disclosed. The method includes the steps of: providing a semiconductor substrate having a gate and a source/drain region thereon; forming a Ni—Pt layer on surface of the gate and the source/drain region; performing a first rapid thermal process to react a portion of the Ni—Pt layer into a silicide layer; removing un-reacted nickel from the first rapid thermal process; removing un-reacted platinum from the first rapid thermal process; performing a second rapid thermal process for lowering the resistance of the silicide layer; and covering a contact etch stop layer (CESL) on the silicide layer after the second rapid thermal process.

### BACKGROUND OF THE INVENTION

1. Field of the Invention

The invention relates to a method for fabricating MOS transistor, and more particularly, to a method of conducting no extra cleaning process after the second rapid thermal process of a salicide process.

2. Description of the Prior Art

Field effect transistors are important electronic devices in the fabrication of integrated circuits, and as the size of the semiconductor device becomes smaller and smaller, the fabrication of the transistors also improves and is constantly enhanced for fabricating transistors with smaller sizes and higher quality.

In the conventional method of fabricating transistors, a gate structure is first formed on a substrate, and a lightly doped drain (LDD) is formed on the two corresponding sides of the gate structure. Next, a spacer is formed on the sidewall of the gate structure and an ion implantation process is performed to form a source/drain region within the substrate by utilizing the gate structure and spacer as a mask. In order to incorporate the gate, source, and drain into the circuit, contact plugs are often utilized for interconnection purposes, in which the contact plugs are composed of conducting metals such as tungsten and copper. Nevertheless, the interconnection between the contact plugs and the silicon material of the gate structure and the source/drain region is usually poor, hence a silicide material is often formed over the surface of the gate structure and the source/drain region to improve the ohmic contact between the contact plugs and the gate structure and the source/drain region.

Today, the process known as self-aligned silicide (salicide) process has been widely utilized to fabricate silicide materials, in which a source/drain region is first formed, a metal layer comprised of cobalt, titanium, or nickel is disposed on the source/drain region and the gate structure, and a first rapid thermal process (RTP) is performed to react the metal layer with the silicon contained within the gate structure and the source/drain region to form a silicide layer. After using a sulfuric acid-hydrogen peroxide mixture (SPM) cleaning to remove un-reactive nickel from the first rapid thermal process, a second RTP is conducted to reduce the sheet resistance of the silicide layer.

Unfortunately, the cleaning process conducted between the aforementioned first and second RTP typically brings in unwanted particles and contaminates the wafer, which lowers the overall fabrication yield substantially. In order to resolve this issue, another cleaning process is often carried after the second RTP to remove these unwanted particles. However, these two cleaning steps not only complicates the entire fabrication process, but also increases overall time expenditure and cost substantially. Hence, how to simplify the conventional salicide process while resolving above issues has become an important task.

### SUMMARY OF THE INVENTION

It is an objective of the present invention to provide a method of fabricating MOS transistor to resolve the above issue of bringing unwanted particles during a salicide process.

According to an embodiment of the present invention, a method for fabricating metal-oxide semiconductor (MOS) transistor is disclosed. The method includes the steps of: providing a semiconductor substrate having a gate and a source/drain region thereon; forming a Ni—Pt layer on surface of the gate and the source/drain region; performing a first rapid thermal process to react a portion of the Ni—Pt layer into a silicide layer; removing un-reacted nickel from the first rapid thermal process; removing un-reacted platinum from the first rapid thermal process; performing a second rapid thermal process for lowering the resistance of the silicide layer; and covering a contact etch stop layer (CESL) on the silicide layer after the second rapid thermal process.

Another aspect of the present invention discloses a method for fabricating MOS transistor. The method includes the steps of: providing a semiconductor substrate having a gate and a source/drain region thereon; forming a Ni—Pt layer and a barrier layer on surface of the gate and the source/drain region; performing a first rapid thermal process to react a portion of the Ni—Pt layer into a silicide layer; performing a first sulfuric acid-hydrogen peroxide mixture (SPM) cleaning process for removing un-reacted nickel and the barrier layer from the first rapid thermal process; performing a hydrochloric acid-hydrogen peroxide mixture (HPM) cleaning process for removing un-reacted platinum from the first rapid thermal process; performing a second sulfuric acid-hydrogen peroxide mixture cleaning process for removing the remaining barrier layer and un-reacted nickel; performing a second rapid thermal process for lowering the resistance of the silicide layer; and covering a contact etch stop layer (CESL) on the silicide layer after the second rapid thermal process.

Another aspect of the present invention discloses a method for fabricating metal-oxide semiconductor (MOS) transistor. The method includes the steps of: providing a semiconductor substrate having a gate and a source/drain region thereon; forming a Ni—Pt layer on surface of the gate and the source/drain region; performing a first rapid thermal process to react a portion of the Ni—Pt layer into a silicide layer; performing a cleaning process for removing un-reacted nickel and un-reacted platinum from the first rapid thermal process; performing a second rapid thermal process for lowering the resistance of the silicide layer; and covering a contact etch stop layer (CESL) on the silicide layer, wherein no cleaning process is conducted between the second rapid thermal process and covering the contact etch stop layer.

These and other objectives of the present invention will no doubt become obvious to those of ordinary skill in the art after reading the following detailed description of the preferred embodiment that is illustrated in the various figures and drawings.

### BRIEF DESCRIPTION OF THE DRAWINGS

FIGS. 1-3 illustrate a method for fabricating a MOS transistor according to a preferred embodiment of the present invention.

FIGS. 4 is a flow chart diagram illustrating the process after the aforementioned first RTP according to the preferred embodiment of the present invention.

FIGS. 5-8 are perspective diagrams illustrating fabrication process conducted after the second RTP.

### DETAILED DESCRIPTION

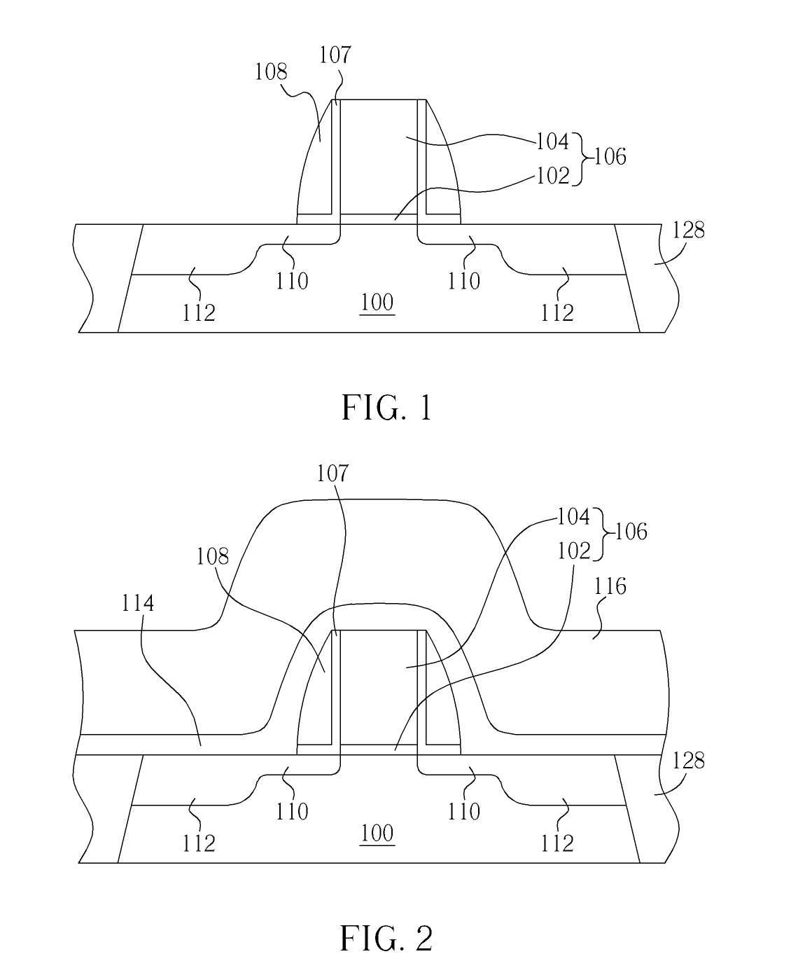

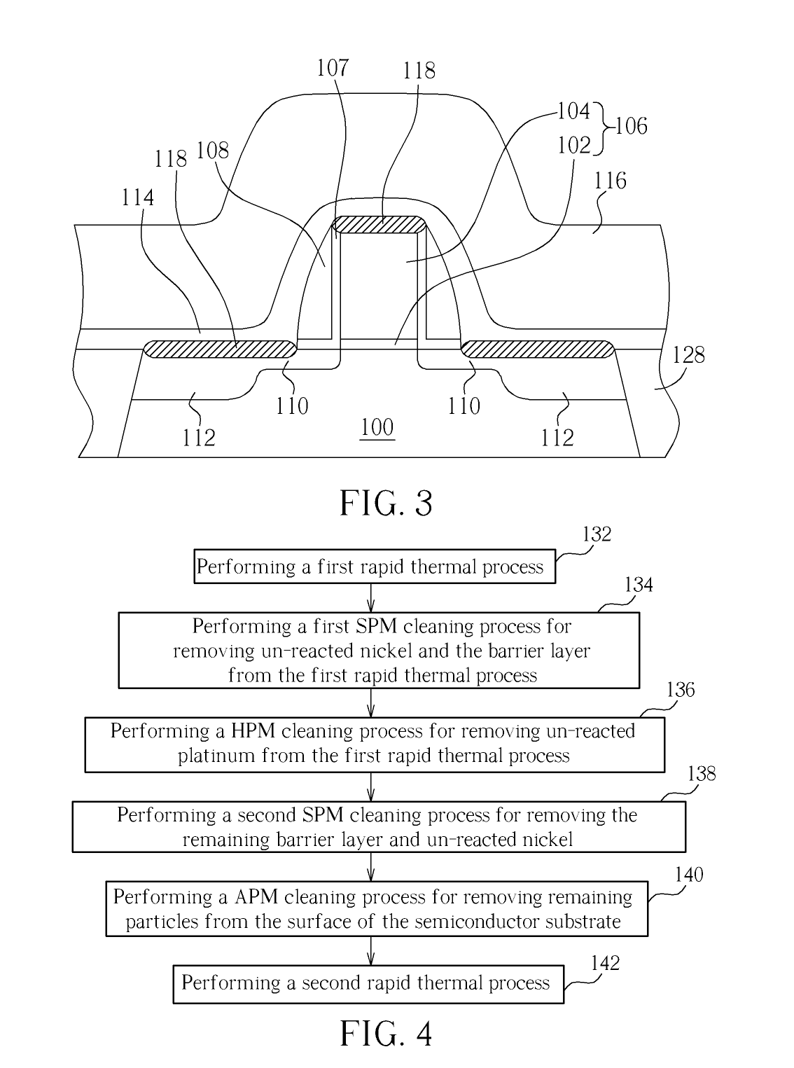

Referring to FIGS. 1-3, FIGS. 1-3 illustrate a method for fabricating a MOS transistor according to a preferred embodiment of the present invention. As shown in FIG. 1, a semiconductor substrate 100, such as a wafer or a silicon-on-insulator (SOI) substrate is provided. Preferably, the semiconductor substrate 100 may include structures such as gate electrode, source/drain regions, isolation regions, word lines, diodes, fuses, or resistors depending on different product demands and fabrication processes. According to the preferred embodiment of the present invention, a gate structure 106, source/drain region 112, and isolating region 128 of a MOS transistor are exemplified in this embodiment. As shown in FIG. 1, the gate structure 106 includes a gate dielectric layer 102 and gate electrode 104. The gate dielectric layer 102 is preferably composed of insulating material such as silicon nitrides, oxides, oxynitrides, or metal oxides, and the gate conductive layer 104 is composed of conductive material such as doped polysilicon.

Next, a lightly doped ion implantation process is performed by using the gate electrode 104 as mask to implant dopants into the semiconductor substrate 100 adjacent to two sides of the gate conductive layer 104 for forming a source/drain extension or a lightly doped source/drain 110. The implanted dopants are preferably selected according to the type of MOS transistor being fabricated. For instance, n-type dopants including phosphorus or arsenic would be implanted for fabricating a NMOS transistor, whereas p-type dopants including boron would be used for a PMOS transistor. Additionally, a spacer (not shown) could be selectively formed on the sidewall of the gate structure 106 through hot oxidation prior to the formation of the source/drain extension or the lightly doped source/drain 110. By doing so, this selectively formed spacer and the gate electrode 104 could be using as a mask during the lightly doped ion implantation process.

A liner 107 composed of silicon oxide and one or more spacer 108 composed of silicon nitride compound are selectively formed on the sidewall of the gate structure 106, in which the liner 107 and the spacer 108 could be composed of any dielectric material. Next, a heavily doped ion implantation is performed by using the gate electrode 104 and the spacer 108 as mask to implant heavy dopants into the semiconductor substrate 100 for forming a source/drain region 112. Similar to the ion implantation conducted for the aforementioned lightly doped source/drain 110, dopants implanted for a NMOS transistor would include phosphorus or arsenic, whereas dopants implanted for a PMOS transistor would include boron. Next, a thermal annealing process is performed by using a temperature between 1000° C. to 1050° C. to activate the dopants within the semiconductor substrate 100 and repair the damage of the crystal lattice structure of the semiconductor substrate 100 caused during the ion implantation process.

In addition to the aforementioned process, the order for fabricating the spacer, the lightly doped source/drain and the source/drain region could be adjusted according to the demand of the product, which are all within the scope of the present invention. For instance, in one embodiment, one or more spacer could be formed, the source/drain is formed thereafter, and after removing the spacer or the outer most layer of the spacer, ion implantation is conducted to form the lightly doped drain region. In another embodiment, two recesses could be formed in the substrate with respect to two sides of the gate structure prior to the formation of the source drain region, and an epitaxial layer could be grown through selective epitaxial growth process in the two recesses thereafter. The epitaxial layer is preferably composed of material suitable for NMOS transistor, such as SiC, or material suitable for PMOS transistor, such as SiGe.

Next, a salicide process is conducted to form silicide layers. As shown in FIG. 2, a thin film deposition process is conducted to deposit a metal layer 114 with approximately 98 angstroms and a barrier layer 116 composed of TiN on the surface of the gate structure 106 and the source/drain region 112. The metal layer 114 preferably comprises a first metal comprising platinum (Pt), nickel (Ni), cobalt (Co), titanium (Ti) or alloys of the aforementioned metals used to form silicide and, a second metal comprising Pt, Co, palladium (Pd), manganese (Mn), tantalum (Ta), ruthenium (Ru) or alloys of the aforementioned metals in a low concentration. The second metal is added with a concentration of 3-8% (wt %) and is preferably used to improve a thermal stability of the salicide and prevent the salicide from agglomeration which increases contact resistance and junction leakage. In this embodiment, the first metal is Ni and the second metal is Pt. However, in a modification of the preferred embodiment, the first metal is not limited to Ni, but can be Co or Pt; and, the second metal used to improve thermal stability is not limited to Pt, but can also be Pd, Mo, Ta, or Ru. Next, a first rapid thermal process (RTP) is performed to react the metal layer 114 with silicon in the gate structure 106 and the source/drain 112 and to form intergraded salicides 118. These processes are well known to those skilled in the art and further detailed description is therefore omitted here for brevity.

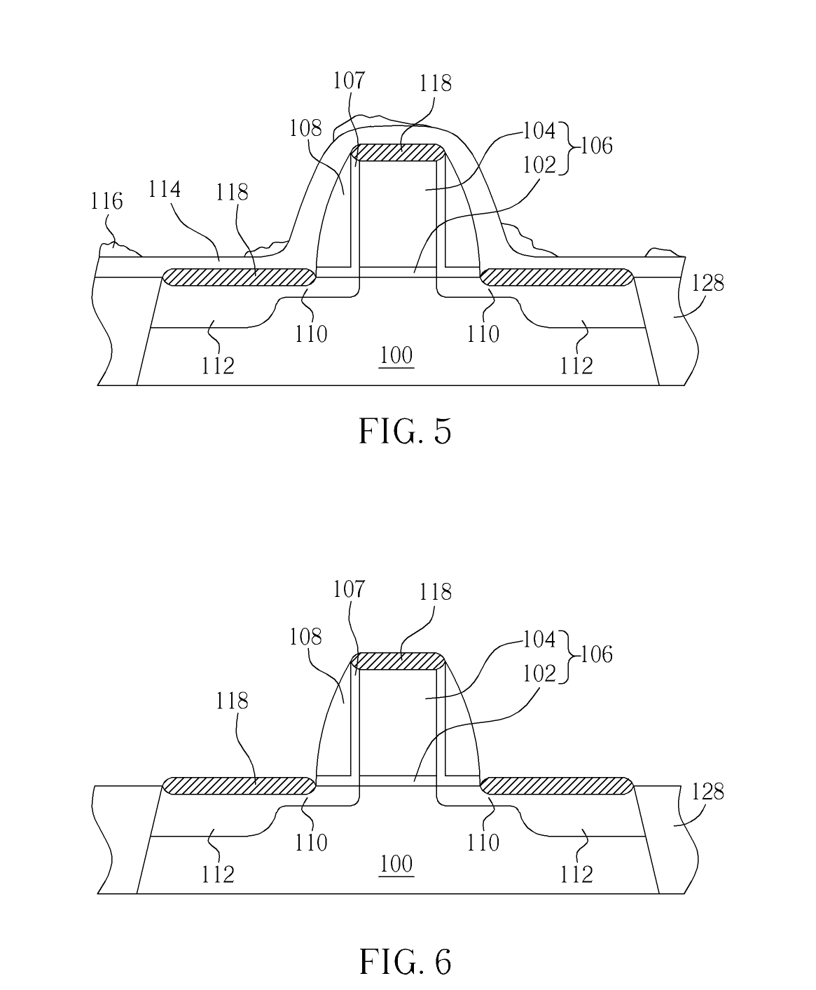

Referring to FIGS. 4-7, FIGS. 4 is a flow chart diagram illustrating the process after the aforementioned first RTP according to the preferred embodiment of the present invention, and FIGS. 5-7 are perspective diagrams illustrating fabrication process corresponding FIG. 4. As shown in the figures presented, step 132 is first carried out to perform the first RTP for reacting the Ni—Pt metal layer with silicon to form integrated silicides. In this embodiment, the temperature of the first RTP is between 300° C. to 320° C., and preferably at 310° C., and the duration of the first rapid thermal process is between 30 seconds to 60 seconds, and preferably at 45 seconds.

In step 134, a first sulfuric acid-hydrogen peroxide mixture (SPM) cleaning process is performed to remove the barrier layer 116 composed of TiN and un-reacted nickel metal from the first RTP, as shown in FIG. 5. In this embodiment, the duration of the first SPM cleaning process is between 500 seconds to 700 seconds, and preferably at 600 seconds. The temperature of the first SPM cleaning process is preferably at 95° C., and the volume percent of sulfuric acid to hydrogen peroxide in SPM is preferably 800:200.

In step 136, a hydrochloric acid-hydrogen peroxide mixture (HPM) cleaning process is conducted to remove un-reactive platinum from the first RTP. In this embodiment, the duration of the HPM cleaning process is between 210 seconds to 410 seconds, and preferably at 310 seconds. The temperature of the HPM cleaning process is preferably at 50° C., and the volume percent of hydrochloric acid to hydrogen peroxide in HPM is preferably 800:600.

In step 138, a second SPM cleaning process is performed to once more remove the remaining barrier layer 116 and un-reacted nickel, as shown in FIG. 6. The duration of the second SPM cleaning process is between 80 seconds to 280 seconds, and preferably at 180 seconds. The temperature of the second SPM cleaning process is preferably at 95° C., and the volume percent of sulfuric acid to hydrogen peroxide in SPM is preferably 800:200.

In step 140, an ammonia hydrogen peroxide mixture (APM) cleaning process is conducted to remove remaining particles from the surface of the semiconductor substrate 100. In this embodiment, the duration of the APM cleaning process is between 20 seconds to 220 seconds, and preferably at 120 seconds. The temperature of the APM cleaning process is preferably at 60° C., and the volume percent of ammonia, hydrogen peroxide, and water in APM is preferably 60:120:2400.

In step 142, a second RTP is conducted to transform the integrated silicide 118 into a silicide layer with lower sheet resistance. In this embodiment, the second RTP is preferably a spike anneal process, and the temperature of this process is preferably 500° C.

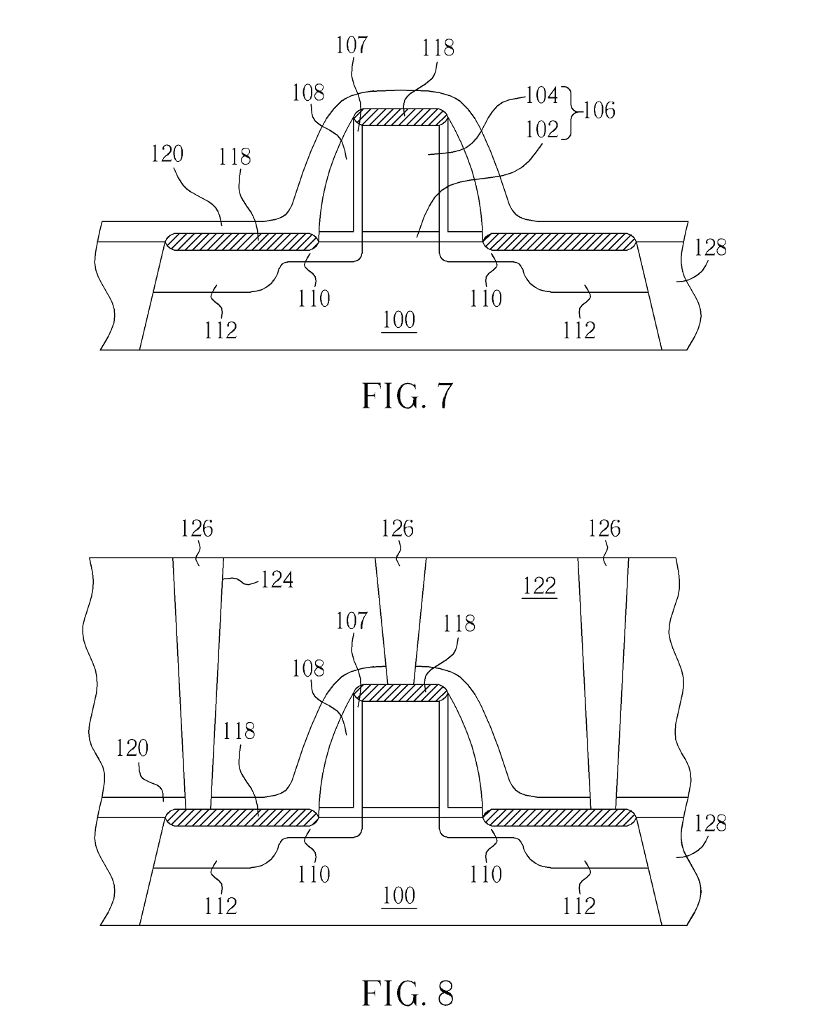

After the second RTP is conducted, as shown in FIG. 7, a contact etch stop layer (CESL) 120 is formed on top of the silicide layer 118 as no extra cleaning process is performed between the second RTP and the formation of the CESL 120. The material of the CESL 120 is preferably dependent upon the nature of the NMOS or PMOS transistor, such that the CESL 120 could either be a CESL 120 with tensile stress or compressive stress.

As shown in FIG. 8, an interlayer dielectric layer 122 composed of oxides is deposited on the semiconductor substrate 100 to cover the CESL 120. The interlayer dielectric layer 122 could be composed of nitrides, oxides, carbides, low-k dielectric material or combination thereof.

Next, a contact plug fabrication is performed by using a patterned photoresist (not shown) as mask to etch through the interlayer dielectric layer 122 and the CESL 120 for forming a plurality of contact openings 124 exposing the silicide layer 118 on top of the gate structure 106 and the source/drain region 112. A metal composed of tungsten, TiN or other conductive material is then deposited in the contact openings 124 for forming a plurality of contact plugs 126 electrically connecting the silicide layer 118. This completes the formation of a MOS transistor with silicides.

Overall, the present invention uses different chemical solvents to remove un-reacted nickel and platinum and contaminating particles from the surface of the semiconductor substrate between the first RTP and second RTP of the salicide process. By doing so, no extra cleaning process is conducted after the second RTP and contact etch stop layer or interlayer dielectric layer could be formed directly thereafter. According to a preferred embodiment of the present invention, a first SPM clean, a HPM clean, a second SPM clean, and an APM clean are conducted between the two RTP. Preferably, the first SPM clean is first performed to remove the barrier layer and un-reacted nickel, the HPM clean is conducted to remove un-reacted platinum from the first RTP, the second SPM is conducted to remove remaining barrier layer and un-reacted nickel, and the APM clean is performed thereafter to remove particles from the surface of the semiconductor substrate.

As particles brought in from the first RTP are typically adhered onto the semiconductor substrate due to the raised temperature of second RTP, the present invention preferably removes these particles as the aforementioned un-reacted metals are removed. Consequently, no extra cleaning process is conducted after the second RTP and the fabrication process is simplified substantially.

Those skilled in the art will readily observe that numerous modifications and alterations of the device and method may be made while retaining the teachings of the invention.

1. A method for fabricating metal-oxide semiconductor (MOS) transistor, comprising:
providing a semiconductor substrate having a gate and a source/drain region thereon;
forming a Ni—Pt layer on surface of the gate and the source/drain region;
forming a barrier layer on surface of the Ni—Pt layer;
performing a first rapid thermal process to react a portion of the Ni—Pt layer into a silicide layer;
using a first sulfuric acid-hydrogen peroxide mixture (SPM) for removing un-reacted nickel from the first rapid thermal process;
using a hydrochloric acid-hydrogen peroxide mixture (HPM) for removing un-reacted platinum from the first rapid thermal process;
using a second sulfuric acid-hydrogen peroxide mixture for removing the remaining barrier layer and un-reacted nickel from the Ni—Pt layer after using the hydrochloric acid-hydrogen peroxide mixture for removing un-reacted platinum;
performing a second rapid thermal process for lowering the resistance of the silicide layer; and
covering a contact etch stop layer (CESL) on the silicide layer after the second rapid thermal process.

2. The method of claim 1, wherein the temperature of the first rapid thermal process is between 300° C. to 320° C.

3. The method of claim 1, wherein the duration of the first rapid thermal process is between 30 seconds to 60 seconds.

4. (canceled)

5. The method of claim 1, wherein the barrier layer comprises TiN.

6. (canceled)

7. (canceled)

8. The method of claim 1, further comprising conducting no cleaning process between the second rapid thermal process and the step of covering the contact etch stop layer on the silicide layer.

9. A method for fabricating MOS transistor, comprising:
providing a semiconductor substrate having a gate and a source/drain region thereon;
forming a Ni—Pt layer and a barrier layer on surface of the gate and the source/drain region;
performing a first rapid thermal process to react a portion of the Ni—Pt layer into a silicide layer;
performing a first sulfuric acid-hydrogen peroxide mixture (SPM) cleaning process for removing un-reacted nickel and the barrier layer from the first rapid thermal process;
performing a hydrochloric acid-hydrogen peroxide mixture (HPM) cleaning process for removing un-reacted platinum from the first rapid thermal process;
performing a second sulfuric acid-hydrogen peroxide mixture cleaning process for removing the remaining barrier layer and un-reacted nickel after performing the HPM cleaning process;
performing a second rapid thermal process for lowering the resistance of the silicide layer; and
covering a contact etch stop layer (CESL) on the silicide layer after the second rapid thermal process.

10. The method of claim 9, wherein the temperature of the first rapid thermal process is between 300° C. to 320° C.

11. The method of claim 9, wherein the duration of the first rapid thermal process is between 30 seconds to 60 seconds.

12. The method of claim 9, wherein the barrier layer comprises TiN.

13. The method of claim 9, further comprising conducting no cleaning process between the second rapid thermal process and the step of covering the contact etch stop layer on the silicide layer.

14. The method of claim 9, further comprising performing an ammonium hydrogen peroxide mixture (APM) cleaning process for removing remaining particles from the surface of the semiconductor substrate after performing the second SPM cleaning process and before performing the second rapid thermal process.

15. A method for fabricating metal-oxide semiconductor (MOS) transistor, comprising:
providing a semiconductor substrate having a gate and a source/drain region thereon;
forming a Ni—Pt layer on surface of the gate and the source/drain region;
performing a first rapid thermal process to react a portion of the Ni—Pt layer into a silicide layer;
performing a cleaning process for removing un-reacted nickel and un-reacted platinum from the first rapid thermal process;
performing a second rapid thermal process for lowering the resistance of the silicide layer; and
covering a contact etch stop layer (CESL) on the silicide layer, wherein no cleaning process is conducted between the second rapid thermal process and covering the contact etch stop layer.

16. The method of claim 15, wherein the temperature of the first rapid thermal process is between 300° C. to 320° C.

17. The method of claim 15, wherein the duration of the first rapid thermal process is between 30 seconds to 60 seconds.

18. The method of claim 15, further comprising forming a barrier layer on surface of the Ni—Pt layer.

19. The method of claim 18, wherein the cleaning process comprises:
using a first sulfuric acid-hydrogen peroxide mixture (SPM) for removing un-reacted nickel and the barrier layer from the first rapid thermal process;
using a hydrochloric acid-hydrogen peroxide mixture (HPM) for removing un-reacted platinum from the first rapid thermal process;
using a second sulfuric acid-hydrogen peroxide mixture for removing the remaining barrier layer and un-reacted nickel from the Ni—Pt layer; and
using an ammonium hydrogen peroxide mixture (APM) for removing remaining particles from the surface of the semiconductor substrate.

20. The method of claim 18, wherein the barrier layer comprises TiN.
